(19) United States
(12) Patent Application Publication
(10) Pub. No.: US 2021/0208314 A1
(43) Pub. Date: Jul. 8, 2021

(54) TRANSPARENT SUBSTRATE, METHOD FOR PREPARING THE SAME, AND OLED DISPLAY DEVICE

(71) Applicant: BOE TECHNOLOGY GROUP CO., LTD., Beijing (CN)

(72) Inventors: Yuanzheng GUO, Beijing (CN); Ping SONG, Beijing (CN); Weinan DAI, Beijing (CN); Ming Che HSIEH, Beijing (CN); Shiming SHI, Beijing (CN)

(21) Appl. No.: 16/081,075

(22) PCT Filed: Jan. 8, 2018
(86) PCT No.: PCT/CN2018/071725

§ 371 Date: Aug. 30, 2018

(30) Foreign Application Priority Data
Jun. 14, 2017 (CN) 201710446830.0

(51) Int. Cl. G02B 5/02; H01L 51/52; B29C 59/02; B29D 11/00

(52) U.S. Cl. CPC G02B 5/0231; H01L 51/5268; G02B 5/0215; H01L 51/0097; B29C 59/022; B29C 59/026; B29D 11/00788; G02B 5/0268

(57) ABSTRACT

Embodiments of the present disclosure relate to a transparent substrate, a method for preparing the same, and an OLED display device. A transparent substrate includes a first transparent film, and a second transparent film arranged on the first transparent film. An interface between the first transparent film and the second transparent film is provided with a light scattering structure.

### CROSS REFERENCE TO RELATED APPLICATIONS

This patent application is a National Stage Entry of PCT/CN2018/071725 filed on Jan. 8, 2018, which claims the benefit and priority of Chinese Patent Application No. 201710446830.0 filed on Jun. 14, 2017, the disclosures of which are incorporated herein by reference in their entirety as part of the present application.

### BACKGROUND

Embodiments of the present disclosure relate to the field of display technologies, and more particularly, to a transparent substrate, a method for preparing the same, and an OLED display device.

Organic light-emitting diode (OLED) display devices, also referred to organic electroluminescent display devices, are display devices different from conventional liquid crystal display (LCD). This display technology has advantages such as simple structure, self-luminescence, high contrast, small thickness, wide view angle, quick response speed, and is applicable to flexible panels. Therefore, OLED has become one of important development directions of a new generation of display apparatuses and has attracted more and more attentions.

### BRIEF DESCRIPTION

Embodiments of the present disclosure provide a transparent substrate, a method for preparing the same, and an OLED display device.

An aspect of the present disclosure provides a transparent substrate which includes a first transparent film, and a second transparent film arranged on the first transparent film. An interface between the first transparent film and the second transparent film is provided with a light scattering structure.

In an embodiment of the present disclosure, the light scattering structure includes a recess formed in the first transparent film.

In an embodiment of the present disclosure, the light scattering structure further includes a lens structure formed by filling the recess with a material of the second transparent film.

In an embodiment of the present disclosure, a cross section of the light scattering structure in parallel with a plane of the first transparent film or the second transparent film is a hexagon.

In an embodiment of the present disclosure, both the first transparent film and the second transparent film are flexible.

In an embodiment of the present disclosure, both the first transparent film and the second transparent film include polyimide.

In an embodiment of the present disclosure, a refractive index of the second transparent film is smaller than that of the first transparent film.

Another aspect of the present disclosure provides an OLED display device, which includes the transparent substrate described in any one of embodiments of the transparent substrate mentioned herein.

Another aspect of the present disclosure provides a method for preparing a transparent substrate, which includes forming a first transparent film on a substrate, and forming a second transparent film on the first transparent film. An interface between the first transparent film and the second transparent film is provided with a light scattering structure.

In an embodiment of the present disclosure, the method further includes forming a recess in the first transparent film to produce the light scattering structure.

In an embodiment of the present disclosure, forming the recess in the first transparent film includes applying first solution onto the substrate, the first solution including a first solvent having a first boiling point and a second solvent having a second boiling point, where the first boiling point is lower than the second boiling point, performing a first drying treatment on the first solution to cause the first solvent to escape and form a partially dried film with a hardened surface, and performing a second drying treatment on the partially dried film to cause the second solvent to escape from the hardened surface of the partially dried film to form a plurality of recesses.

In an embodiment of the present disclosure, a temperature of the first drying treatment is about 50°, and a temperature of the second drying treatment is about 100°.

In an embodiment of the present disclosure, a solvend of the first solution includes polyimide. The first solvent includes one or more of dichloromethane, tetrahydrofuran, acetonitrile, acetone, and chloroform. The second solvent includes one or more of N-Methyl pyrrolidone, N,N-dimethylacetamide, N,N-dimethylformamide, γ-butyrolactone, and ethylene glycol monobutyl ether.

In an embodiment of the present disclosure, a ratio of the first solvent in the first solution is about 30%-70%.

In another embodiment of the present disclosure, forming the recess in the first transparent film includes applying second solution onto the substrate, performing a third drying treatment on the second solution to form a partially dried film, impressing the partially dried film by means of a mold having a bump structure to form the recess in the partially dried film, and performing a fourth drying treatment on the partially dried film.

In an embodiment of the present disclosure, a cross section of the bump structure in parallel with a surface of the mold is a hexagon.

In an embodiment of the present disclosure, a solvend of the second solution includes polyimide. A solvent of the second solution includes one or more of dichloromethane, tetrahydrofuran, acetonitrile, acetone, chloroform, N-Methyl pyrrolidone, N,N-dimethylacetamide, N,N-dimethylformamide, γ-butyrolactone, and ethylene glycol monobutyl ether.

In an embodiment of the present disclosure, forming the second transparent film includes applying third solution onto the first transparent film, where a viscosity of the third solution is configured such that the third solution can cover but does not fill the recess, and drying the third solution to form the second transparent film.

In an embodiment of the present disclosure, a solvend of the third solution includes polyimide, and a solvent of the third solution includes one or more of γ-butyrolactone, ethylene glycol monobutyl ether, dichloromethane, tetrahydrofuran, acetonitrile, acetone, and chloroform.

In another embodiment of the present disclosure, forming the second transparent film includes applying fourth solution onto the first transparent film, wherein a viscosity of the fourth solution is configured such that the fourth solution can fill the recess, and drying the fourth solution to form the second transparent film.

In an embodiment of the present disclosure, a solvend of the fourth solution includes polyimide, and a solvent of the fourth solution includes one or more of γ-butyrolactone, ethylene glycol monobutyl ether, dichloromethane, tetrahydrofuran, acetonitrile, acetone, and chloroform.

Further adaptive aspects and scopes become apparent from the description provided herein. It should be understood that various aspects of the present disclosure may be implemented separately or in combination with one or more other aspects. It should also be understood that the description in the present disclosure and objectives which are intended to be merely described in the specific embodiments are not intended to limit the scope of the present disclosure.

### BRIEF DESCRIPTION OF THE DRAWINGS

The accompanying drawings set forth herein are merely for the purpose of describing the selected embodiments and are not all possible implementations and are not intended to limit the scope of the present disclosure, in which

FIG. 1 illustrates a schematic diagram of an exemplary transparent substrate according to an embodiment of the present disclosure;

FIG. 2 illustrates a schematic optical path diagram of light in the transparent substrate as shown in FIG. 1;

FIG. 3 illustrates a schematic diagram of another exemplary transparent substrate according to an embodiment of the present disclosure;

FIGS. 4A and 4B respectively illustrate two schematic optical path diagrams of light in the transparent substrate as shown in FIG. 3;

FIG. 5 illustrates a schematic flowchart of a method for preparing a transparent substrate according to an embodiment of the present disclosure;

FIG. 6 illustrates a schematic flowchart of a method of forming a recess in a first transparent film according to an embodiment of the present disclosure;

FIG. 7 illustrates another schematic flowchart of a method of forming a recess in a first transparent film according to an embodiment of the present disclosure;

FIG. 8 illustrates a schematic plane diagram of a mold used in the embodiment as shown in FIG. 7;

FIG. 9 illustrates a schematic flowchart of a method of forming a second transparent film in Step S502 of FIG. 5 according to a specific embodiment; and

FIG. 10 illustrates a schematic flowchart of a method of forming a second transparent film in Step S502 of FIG. 5 according to another specific embodiment.

Throughout the various diagrams of these drawings, corresponding reference numerals indicate corresponding parts or features.

### DETAILED DESCRIPTION

The exemplary embodiments will now be described more fully with reference to the accompanying drawings.

Notably, the figures and the examples below are not meant to limit the scope of the present disclosure. Where certain elements of the present disclosure may be partially or fully implemented using known components (or methods or processes), only those portions of such known components (or methods or processes) that are necessary for an understanding of the present disclosure will be described, and the detailed descriptions of other portions of such known components will be omitted so as not to obscure the present disclosure. Further, various embodiments encompass present and future known equivalents to the components referred to herein by way of illustration.

As used herein and in the appended claims, the singular form of a word includes the plural, and vice versa, unless the context clearly dictates otherwise. Thus, singular words are generally inclusive of the plurals of the respective terms. Similarly, the words “include” and “comprise” are to be interpreted inclusively rather than exclusively.

An OLED display device structurally includes a plurality of layers, for example, a substrate, an anode, a hole transport layer, an organic light emitting layer, an electron transport layer, and a cathode. When a voltage is applied between the anode and the cathode, the cathode and the anode respectively inject electrons and holes into an organic layer, such that these electrons and holes migrate to the organic light emitting layer through the electron transport layer and the hole transport layer respectively. The electrons and holes recombine in the organic light emitting layer to produce energy, and finally energy is released by way of light emission.

In the OLED display device, light emitted from the light emitting layer is reflected and/or refracted by the respective layers of the OLED, and then exits from the substrate. However, the respective layers of the OLED have different refractive indexes, so light emitted from the light emitting layer may be reflected at interfaces between layers, and particularly a total reflection is liable to occur at each interface (for example, an interface between the substrate and air). A part of reflected or totally reflected light is further reflected or refracted at respective layers, and is finally exhausted inside the device, and thus the light cannot be emitted from the transparent substrate. Therefore, the light emission efficiency of the OLED display device is lower, which generally is not more than 20%.

An embodiment of the present disclosure provides a transparent substrate, which includes a first transparent film, and a second transparent film arranged on the first transparent film. An interface between the first transparent film and the second transparent film is provided with a light scattering structure.

In the case that the transparent substrate provided by this embodiment of the present disclosure is used in the OLED display device, at least a part of light emitted from the light emitting layer is scattered by the light scattering structure, which may at least partially destroy the total reflection of the light at respective interfaces (for example, the interface between the transparent substrate and air) of the OLED display device, such that more light may exit from the transparent substrate. Therefore, the transparent substrate having such configuration may increase the light emission efficiency. Moreover, the second transparent film is formed on the first transparent film, which may play a role in planarization. In the case that the transparent substrate with such structure is used in the OLED display device, preparation of other film layers (for example, a TFT layer, an anode layer, a light-emitting layer, and a cathode layer) thereon is not affected.

Term “transparent” herein should be interpreted broadly, which not only may include the situation of “completely transparent”, but also may include the situation of “partially transparent”.

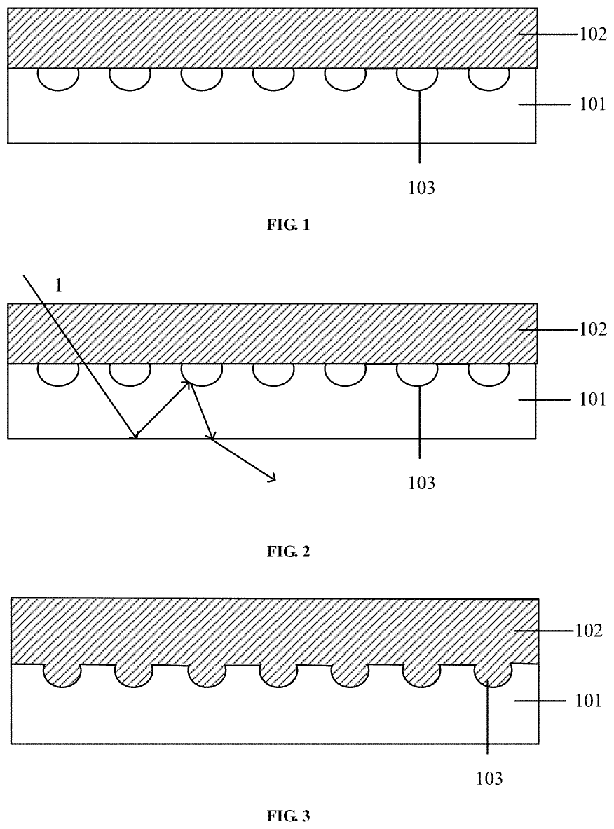

FIG. 1 illustrates a schematic diagram of an exemplary transparent substrate according to an embodiment of the present disclosure. As shown in FIG. 1, the transparent substrate includes a first transparent film 101, a second transparent film 102, and a light scattering structure 103 at an interface between the first transparent film 101 and the second transparent film 102.

In the embodiment of the present disclosure, the light scattering structure 103 may include a recess formed in the first transparent film 101. The second transparent film 102 covers on the first transparent film 101, such that an opening of the recess is sealed by the second transparent film 102, and thus a sealed gap is formed at the interface between the first transparent film 101 and the second transparent film 102. The sealed gap may serve as the light scattering structure 103.

FIG. 2 illustrates a schematic optical path diagram of light in the transparent substrate as shown in FIG. 1. As shown in FIG. 2, in the case that light 1 incident on the interface between the first transparent film 101 and air is totally reflected at this interface, at least a part of the light totally reflected is incident on the light scattering structure 103 (for example, the sealed gap as shown in FIG. 2) and is scattered by the light scattering structure 103, and then at least a part of scattered light may be again incident upon the interface between the first transparent film 101 and air at a smaller incident angle. The smaller incident angle is likely smaller than a critical angle of the total reflection at the interface between the first transparent film 101 and air. Therefore, this part of scattered light may exit from the first transparent film 101. Thus, the light scattering structure 103 formed by such sealed gap (recess) may allow at least a part of the light totally reflected at the interface between the first transparent film 101 and air to exit from the first transparent film 101. Therefore, in the case that the transparent substrate having such structure is used in the OLED display device, the light emission efficiency of the display device may be increased.

In the embodiment of the present disclosure, the light scattering structure may have a micron order, such as 1-10 μm.

In this embodiment, the light scattering structure having a recess shape may be formed by a mold having a bump structure by way of impressing. In this embodiment, a cross section of the light scattering structure in parallel with a plane of the first transparent film or the second transparent film may be a hexagon.

In the embodiment of the present disclosure, both the first transparent film 101 and the second transparent film 102 may be flexible, and thus a flexible transparent substrate may be formed. A flexible display device may be formed in the case that this flexible transparent substrate is used in the OLED display device.

In the embodiment of the present disclosure, both the first transparent film 101 and the second transparent film 102 may include polyimide. The polyimide has high temperature resistance, low temperature resistance, high strength, transparency for light within a visible light wave band, and better flexibility, etc. Therefore, using the polyimide as the substrate of the OLED display device may form a flexible OLED and may enhance the performance of the OLED.

In the embodiment as shown in FIG. 1, the refractive index of the second transparent film may be smaller than that of the first transparent film to avoid the occurrence of total reflection, of light transmitting from the second transparent film to the first transparent film, at the interface between the second transparent film and the first transparent film. However, other embodiments also may be feasible.

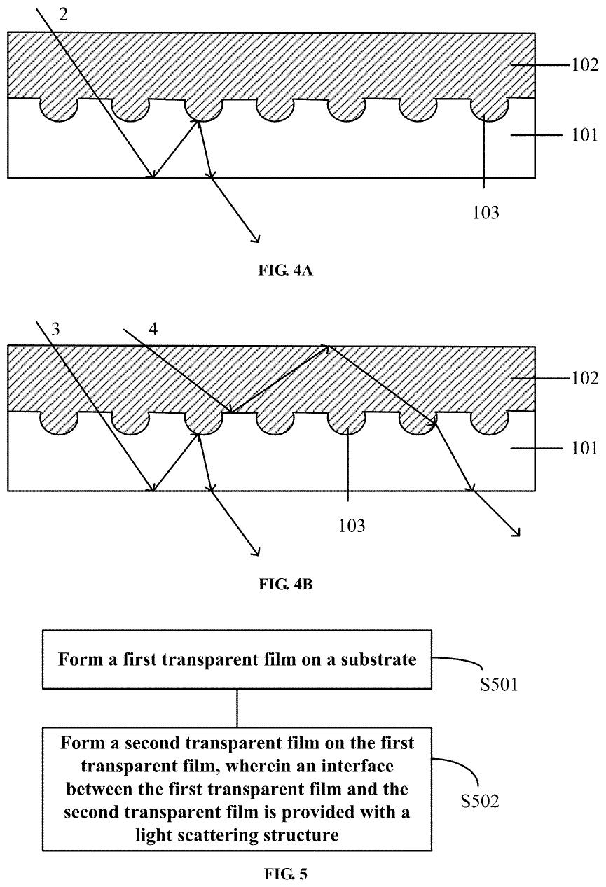

FIG. 3 illustrates a schematic diagram of another exemplary transparent substrate according to an embodiment of the present disclosure. The embodiment as shown in FIG. 3 is similar to the embodiment as shown in FIG. 1, where the light scattering structure 103 is arranged at the interface between the first transparent film 101 and the second transparent film 102. What is different is that the light scattering structure 103 in the embodiment as shown in FIG. 3 is formed by filling the recess with the material of the second transparent film 102. Specifically, in the embodiment as shown in FIG. 3, the recess formed in the first transparent film 101 is filled with the material of the second transparent film 102, thereby forming a lens structure at the interface between the first transparent film 101 and the second transparent film 102. The lens structure may serve as the light scattering structure 103.

FIG. 4A and FIG. 4B respectively illustrate two schematic optical path diagrams of light in the transparent substrate as shown in FIG. 3. As shown in FIG. 4A, in the case that the refractive index of the first transparent film 101 is greater than that of the second transparent film 102, light 2 may be totally reflected at the interface between the first transparent film 101 and air. In such a case, at least a part of light totally reflected is incident on the light scattering structure 103 (the lens structure as shown in FIG. 2) and is scattered by the light scattering structure 103, such that at least a part of the scattered light does not satisfy a total reflection condition at the interface between the first transparent film 101 and air, and thus this part of scattered light may exit from the interface between the first transparent film 101 and air. As shown in FIG. 4B, in the case that the refractive index of the first transparent film 101 is smaller than that of the second transparent film 102, light not only may be totally reflected at the interface between the first transparent film 101 and air, but also may be totally reflected at the interface between the first transparent film 101 and the second transparent film 102. The light 3 totally reflected at the interface between the first transparent film 101 and air has an optical path similar to that is shown in FIG. 4A. At least a part of the light totally reflected is scattered by the light scattering structure 103, such that at least a part of the scattered light may exit from the interface between the first transparent film 101 and air. For the light 4 totally reflected at the interface between the first transparent film 101 and the second transparent film 102, a part of the light totally reflected is reflected by an upper surface of the second transparent film 102, at least a part of the light reflected by the second transparent film 102 may be incident on the light scattering structure 103. The light scattering structure 103 has the same material as that of the second transparent film 102, and thus the refractive index of the light scattering structure 103 is greater than that of the first transparent film 101. Therefore, the light scattering structure may converge light, such that light emitted from the light scattering structure is converged to a certain extent and is incident on the interface between the first transparent film 101 and air at a smaller incident angle, and thus the light may more easily exit from the interface. Accordingly, the transparent substrate provided by this embodiment may increase the light emission efficiency.

It is to be noted that FIG. 2, FIG. 4A and FIG. 4B merely illustrate embodiments of a scattering effect of the light scattering structure 103 on the light totally reflected at the interface between the first transparent film 101 and the second transparent film 102 and the light totally reflected at the interface between the first transparent film 101 and air. However, it should be understood that other embodiments also is feasible. As an example, in the case that the transparent substrate provided by embodiments of the present disclosure is used in the OLED display device, the light scattering structure 103 also may scatter light totally reflected at other interfaces of the OLED display device, such that more light exits from the first transparent film 101. It should also be understood that the light scattering structure not only may scatter light totally reflected at respective interfaces of the OLED display device and then incident on the light scattering structure, but also may scatter light refracted or reflected (not totally reflected) at respective interfaces of the OLED display device and then incident upon the light scattering structure, such that more light exit from the first transparent film 101.

At another aspect of the present disclosure, there is further provided an OLED display device. The OLED display device includes at least one transparent substrate according to the present disclosure, such as at least one transparent substrate according to one or more of the embodiments disclosed above and/or below in further detail. Therefore, reference may be made to the embodiments of the transparent substrate for the alternative embodiments of the OLED display device.

In the OLED display devices provided by embodiments of the present disclosure, the light emission efficiency may be increased by arranging the light scattering structure in the transparent substrate.

At still another aspect of the present disclosure, there is provided a method for preparing a transparent substrate. This method may be used for preparing at least one transparent substrate according to the present disclosure, such as at least one transparent substrate according to one or more of the embodiments disclosed above and/or below in further detail. Therefore, reference may be made to the embodiments of the transparent substrate for a part of alternative embodiments of the method. The method includes the following steps, which may be performed in the given order or in a different order. Furthermore, additional method steps not listed may be provided. Further, additional method steps might be provided which are not listed. Further, two or more or even all of the method steps might be performed at least partially simultaneously. Further, a method step might be performed twice or even more than twice, repeatedly.

FIG. 5 illustrates a schematic flowchart of a method for preparing a transparent substrate according to an embodiment of the present disclosure. As shown in FIG. 5, the method for preparing a transparent substrate includes:

Step S501: forming a first transparent film on a substrate; and

Step S502: forming a second transparent film on the first transparent film. An interface between the first transparent film and the second transparent film is provided with a light scattering structure.

In the method for preparing the transparent substrate provided by this embodiment of the present disclosure, at least a part of light emitted from the light emitting layer is scattered by the light scattering structure, which may at least partially destroy the total reflection condition of the light at the interface between the transparent substrate and air, such that more light may exit from the transparent substrate. Therefore, the transparent substrate having this configuration may increase the light emission efficiency.

In embodiments of the present disclosure, the method for preparing the transparent substrate may further include forming a recess in the first transparent film to produce the light scattering structure.

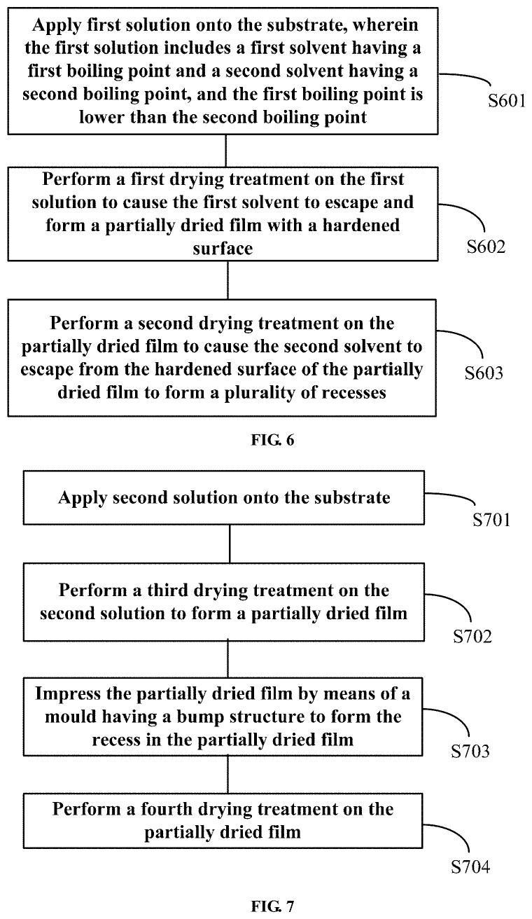

FIG. 6 illustrates a schematic flowchart of a method of forming a recess in a first transparent film according to an embodiment of the present disclosure. As shown in FIG. 6, forming the recess in the first transparent film may include Step S601-Step S603.

In Step S601, first solution is applied onto the substrate. The first solution includes a first solvent having a first boiling point and a second solvent having a second boiling point, wherein the first boiling point is lower than the second boiling point.

In embodiments of the present disclosure, a solvend of the first solution may include polyimide. The first solvent of the first solution may include one or more of dichloromethane, tetrahydrofuran, acetonitrile, acetone and chloroform. The second solvent of the first solution may include one or more of N-Methyl pyrrolidone, N,N-dimethylacetamide, N,N-dimethylformamide, γ-butyrolactone, and ethylene glycol monobutyl ether.

In embodiments of the present disclosure, a volume ratio of the first solvent in the first solution may be about 30%-70%. Correspondingly, the volume ratio of the second solvent in the first solution may be about 70%-30%.

In Step S602, a first drying treatment is performed on the first solution to cause the first solvent to escape and form a partially dried film with a hardened surface.

In this step, the first drying treatment may be, for example, low-temperature Hot Vacuum Clean Dryer treatment, which allows the first solution to form a film having a dried surface. A temperature of the first drying treatment may be, for example, 50°.

In Step S603, a second drying treatment is performed on the partially dried film to cause the second solvent to escape from the hardened surface of the partially dried film to form a plurality of recesses.

In this step, the second drying treatment may be, for example, high-temperature Hot Vacuum Clean Dryer treatment, which allows the second solvent to abruptly and significantly escape from the hardened surface of the partially dried film to form the recesses in the first transparent film. These recesses are retained in the first transparent film after the first transparent film is cured.

In embodiments of the present disclosure, the first solution may have a higher viscosity, for example, a viscosity of 7,000 cp, such that the recesses formed when the second solvent escapes may be retained in the first transparent film.

FIG. 7 illustrates another schematic flowchart of a method of forming a recess in a first transparent film according to an embodiment of the present disclosure. As shown in FIG. 7, forming the recess in the first transparent film includes Step S701-Step S704.

In Step 701, second solution is applied onto the substrate.

In this embodiment, a solvend of the second solution may include polyimide. A solvent of the second solution may include one or more of dichloromethane, tetrahydrofuran, acetonitrile, acetone, chloroform, N-Methyl pyrrolidone, N,N-dimethylacetamide, N,N-dimethylformamide, γ-butyrolactone, and ethylene glycol monobutyl ether.

In Step 702, a third drying treatment is performed on the second solution to form a partially dried film.

In this step, the third drying treatment may be, for example, a Hot Vacuum Clean Dryer treatment. Through the third drying treatment, about 40%-80% of the solvent in the first solution may escape from the first solution, such that partially dried film with the dried surface may be formed.

In Step 703, the partially dried film is impressed by means of a mold having a bump structure to form the recess in the partially dried film.

In an alternative embodiment, as shown in FIG. 8, a cross section of the bump structure 801 in parallel with a working surface of the mold may be a hexagon. Therefore, a recess whose section in parallel with a plane of the substrate is hexagonal may be formed in the partially dried film. It is to be understood that other shapes (for example, a circular, or rectangular shape) of the cross section of the bump structure also may be feasible.

In Step 704, a fourth drying treatment is performed on the partially dried film.

In this step, the fourth drying treatment also may be the Hot Vacuum Clean Dryer treatment. Through the fourth drying treatment, more than 90% of the solvent in the first solution may escape, such that the shape of the recess structure is retained.

It is to be understood that the first solution may be further cured after the third drying treatment and the fourth drying treatment to form the cured first transparent film.

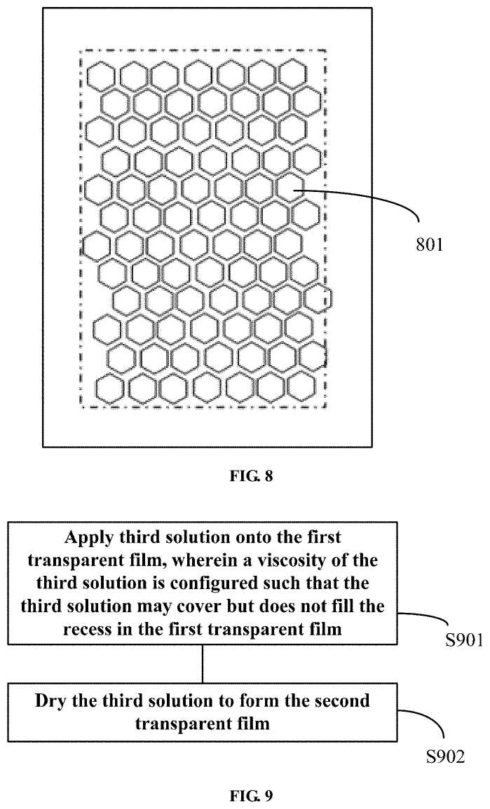

FIG. 9 illustrates a schematic flowchart of a method of forming a second transparent film in Step S502 of FIG. 5 according to a specific embodiment. In the embodiment as shown in FIG. 9, the second transparent film may be formed through Steps S901-S902.

In Step S901, third solution is applied onto the first transparent film. A viscosity of the third solution is configured such that the third solution may cover but does not fill the recess in the first transparent film. In this step, the third solution may have a high viscosity, such that the third solution has poorer fluidity. In such a case, when the third solution is applied onto the first transparent film, the third solution may not fill but merely cover the recess in the first transparent film, thereby forming a sealed gap that may serve as the light scattering structure.

In this embodiment of the present disclosure, a solvend of the third solution may include polyimide, and a solvent of the third solution may include one or more of γ-butyrolactone, ethylene glycol monobutyl ether, dichloromethane, tetrahydrofuran, acetonitrile, acetone, and chloroform.

In Step S902, the third solution is dried to form the second transparent film.

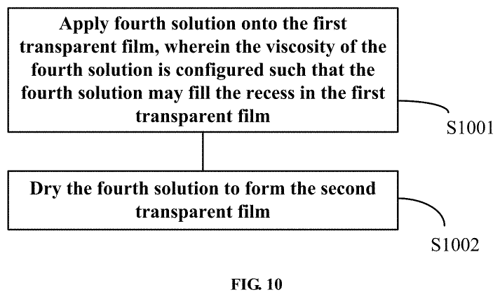

FIG. 10 illustrates a schematic flowchart of a method of forming a second transparent film in Step S502 of FIG. 5 according to another specific embodiment. In the embodiment as shown in FIG. 10, the second transparent film may be formed through Steps S1001-S1002.

In Step S1001, fourth solution is applied onto the first transparent film. The viscosity of the fourth solution is configured such that the fourth solution may fill the recess in the first transparent film. In this step, the fourth solution may have a low viscosity. In such a case, the fourth solution has better fluidity. In such a case, when the fourth solution is applied onto the first transparent film, the fourth solution may fill the recess in the first transparent film because the fourth solution has better fluidity, thereby forming a lens structure that may serve as the light scattering structure.

In embodiments of the present disclosure, a solvend of the fourth solution may include polyimide, and a solvent of the fourth solution also may include one or more of γ-butyrolactone, ethylene glycol monobutyl ether, dichloromethane, tetrahydrofuran, acetonitrile, acetone, and chloroform.

In embodiments of the present disclosure, both the third solution and the fourth solution may be made up of the same solvend and solvent. In embodiments of the present disclosure, the third solution and the fourth solution having different viscosities may be obtained by changing the concentration of the solvend, such that the third solution may cover but does not fill the recess in the first transparent film, whereas the fourth solution may fill the recess in the first transparent film.

In Step S1002, the fourth solution is dried to form the second transparent film.

The foregoing description of the embodiment has been provided for purpose of illustration and description. It is not intended to be exhaustive or to limit the application. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the application, and all such modifications are included within the scope of the application.

1. A transparent substrate comprising:
a first transparent film; and
a second transparent film arranged on the first transparent film, wherein an interface between the first transparent film and the second transparent film is provided with a light scattering structure.

2. The transparent substrate according to claim 1, wherein the light scattering structure comprises a recess formed in the first transparent film.

3. The transparent substrate according to claim 2, wherein the light scattering structure further comprises a lens structure formed by filling the recess with a material of the second transparent film.

4. The transparent substrate according to claim 1, wherein a cross section of the light scattering structure in parallel with a plane of the first transparent film or the second transparent film is a hexagon.

5. The transparent substrate according to claim 1, wherein both the first transparent film and the second transparent film comprise polyimide.

6. The transparent substrate according to claim 1, wherein a refractive index of the second transparent film is smaller than that of the first transparent film.

7. An OLED display device comprising the transparent substrate according to claim 1.

8. A method for preparing a transparent substrate, the method comprising:
forming a first transparent film on a substrate; and
forming a second transparent film on the first transparent film, wherein an interface between the first transparent film and the second transparent film is provided with a light scattering structure.

9. The method according to claim 8 further comprising:
forming a recess in the first transparent film to produce the light scattering structure.

10. The method according to claim 9, wherein forming the recess in the first transparent film comprises:
applying a first solution onto the substrate, the first solution comprising a first solvent having a first boiling point and a second solvent having a second boiling point, wherein the first boiling point is lower than the second boiling point;
performing a first drying treatment on the first solution to cause the first solvent to escape and form a partially dried film with a hardened surface; and
performing a second drying treatment on the partially dried film to cause the second solvent to escape from the hardened surface of the partially dried film to form a plurality of recesses.

11. The method according to claim 10, wherein a temperature of the first drying treatment is approximately 50°, and a temperature of the second drying treatment is approximately 100°.

12. The method according to claim 10, wherein a solvend of the first solution comprises polyimide, wherein the first solvent comprises at least one of dichloromethane, tetrahydrofuran, acetonitrile, acetone, and chloroform, and wherein the second solvent comprises at least one of N-Methyl pyrrolidone, N,N-dimethylacetamide, N,N-dimethylformamide, γ-butyrolactone, and ethylene glycol monobutyl ether.

13. The method according to claim 9, wherein forming the recess in the first transparent film comprises:
applying a second solution onto the substrate;
performing a third drying treatment on the second solution to form a partially dried film;
impressing the partially dried film by means of a mold having a bump structure to form the recess in the partially dried film; and
performing a fourth drying treatment on the partially dried film.

14. (canceled)

15. The method according to claim 13, wherein a solvend of the second solution comprises polyimide, and wherein a solvent of the second solution comprises at least one of dichloromethane, tetrahydrofuran, acetonitrile, acetone, chloroform, N-Methyl pyrrolidone, N,N-dimethylacetamide, N,N-dimethylformamide, γ-butyrolactone, and ethylene glycol monobutyl ether.

16. The method according to claim 10, wherein forming the second transparent film comprises:
applying a third solution onto the first transparent film, a viscosity of the third solution configured such that the third solution can cover but does not fill the recess; and
drying the third solution to form the second transparent film.

17. The method according to claim 16, wherein a solvend of the third solution comprises polyimide, and wherein a solvent of the third solution comprises at least one of γ-butyrolactone, ethylene glycol monobutyl ether, dichloromethane, tetrahydrofuran, acetonitrile, acetone, and chloroform.

18. The method according to claim 10, wherein forming the second transparent film comprises:
applying a fourth solution onto the first transparent film, a viscosity of the fourth solution configured such that the fourth solution can fill the recess; and
drying the fourth solution to form the second transparent film.

19. The method according to claim 18, wherein a solvend of the fourth solution comprises polyimide, and wherein a solvent of the fourth solution comprises at least one of γ-butyrolactone, ethylene glycol monobutyl ether, dichloromethane, tetrahydrofuran, acetonitrile, acetone, and chloroform.

20. The method according to claim 13, wherein forming the second transparent film comprises:
applying a third solution onto the first transparent film, a viscosity of the third solution configured such that the third solution can cover but does not fill the recess; and
drying the third solution to form the second transparent film.

21. The method according to claim 13, wherein forming the second transparent film comprises:
applying a fourth solution onto the first transparent film, a viscosity of the fourth solution configured such that the fourth solution can fill the recess; and
drying the fourth solution to form the second transparent film.
